(19) United States
(12) Patent Application Publication
(10) Pub. No.: US 2017/0291495 A1
(43) Pub. Date: Oct. 12, 2017

(54) Adjustable Capacitance Value For Tuning Oscillatory Systems

(71) Applicant: Siemens Aktiengesellschaft, Muenchen (DE)

(72) Inventors: Manuel Blum, Ottobrunn (DE); Thomas Komma, Ottobrunn (DE); Mirjam Mantel, Haar (DE); Monika Poebl, Muenchen (DE)

(73) Assignee: Siemens Aktiengesellschaft, Muenchen (DE)

(21) Appl. No.: 15/513,681

(22) PCT Filed: Sep. 15, 2015
(86) PCT No.: PCT/EP2015/071075

§ 371 Date: Mar. 23, 2017

(30) Foreign Application Priority Data
Sep. 25, 2014 (DE) 10 2014 219 374.5

(51) Int. Cl. B60L 11/18; H03J 3/18

(52) U.S. Cl. CPC B60L 11/18; H03J 3/18; H01G 7/00

(57) ABSTRACT

The present disclosure relates to tuning oscillatory systems. The teachings thereof may be embodied in a device having an adjustable capacitance value for tuning a first oscillatory system, connectable to a second oscillatory system having an unknown and weak coupling factor. The device may include: a first capacitor having a capacitance dependent upon a voltage; and a DC voltage source having a variable voltage applied to associated terminals; a series-connected arrangement of the DC voltage source and a decoupling element connected in parallel with terminals of the capacitor, to apply a variable bias voltage to the first capacitor. The voltage applied to the terminals of the DC voltage source may depend at least in part on a working frequency of the first oscillatory system.

### CROSS-REFERENCE TO RELATED APPLICATIONS

This application is a U.S. National Stage Application of International Application No. PCT/EP2015/071075 filed Sep. 15, 2015, which designates the United States of America, and claims priority to DE Application No. 10 2014 219 374.5 filed Sep. 25, 2014, the contents of which are hereby incorporated by reference in their entirety.

### TECHNICAL FIELD

The present disclosure relates to tuning oscillatory systems. The teachings thereof may be embodied in a device having an adjustable capacitance value for tuning a first oscillatory system, connectable to a second oscillatory system having an unknown and weak coupling factor.

### BACKGROUND

In devices for the contactless transmission of energy to a corresponding device, electrical energy is transmitted by inductive transmission via a magnetic alternating field in an air-gapped system. The coil system is comprised of two coils: a primary coil, which is supplied by a current source, and a secondary coil, which delivers electrical energy to the consumer.

When a device of this type is employed in motor vehicles, the primary coil is customarily arranged in a charging station on the floor of a parking space. The secondary coil is typically located in the motor vehicle. The air gap in the coil system, a factor affecting the efficiency of transmission, depends on the geometric configuration of the components in which the primary coil and the secondary coil are incorporated. The air gap in the system is primarily dependent on the underfloor clearance of a respective vehicle type. The efficiency of transmission is moreover influenced by the respective lateral arrangement of the primary coil and the secondary coil, associated with a given parking position. In principle, the greater the lateral offset of the primary and secondary coil, the larger the air gap, and consequently the lower the efficiency will be.

### SUMMARY

In principle, such an energy transmission system operates at a fixed working frequency. The working frequency is generally defined by the inductance value of the primary coil, which depends upon the coupling factor of a transformer formed by a primary coil and a secondary coil, or of a coil in combination with a capacitance of the respective coil system. To ensure the desired fixed working frequency of the energy transmission system, which forms a resonant converter, it is necessary, in the case of a variation in load or inductance (caused by the given parking position), to achieve the variable adjustment of the capacitance of the coil system.

In the high-frequency range, variable capacitance diodes are may be used for this purpose. These diodes, however, are only suitable for low voltages and low capacitance values. In resonant converters, such as the type employed in an energy transmission system for the transmission of electrical energy in the field of motor vehicles, however, these are unsuitable, as the power to be transmitted is too high. Typically, in this application of a primary coil system, powers of several kW are transmitted to the secondary coil system.

Bidirectional switching elements can be used to form a variable capacitor network. However, a network of this type is complex, in respect of both spatial requirements and costs required. Moreover, the switching elements generate substantial losses where, as described, the energy transmission system is to operate in a power range of several kW.

The teachings of the present disclosure enable devices with an adjustable capacitance value, wherein the capacitance value can be adjusted in a simple manner, and suitable for use in an energy transmission system designed for the transmission of powers of the order of several kW.

Some embodiments include a device having an adjustable capacitance value for tuning a first oscillatory system (10), provided for coupling with a second oscillatory system (20) having an unknown and weak coupling factor. The device may comprise a first capacitor (Cᵥₐᵣ), the capacitance of which is dependent upon a voltage, and a DC voltage source (DCᵥₐᵣ), the voltage of which applied to the terminals thereof can be controlled, wherein the series-connected arrangement of the DC voltage source (DCᵥₐᵣ) and a decoupling element (Lₑₙₜₖ) is connected in parallel with the terminals of the capacitor, in order to apply a variable bias voltage to the first capacitor (Cᵥₐᵣ), and wherein the voltage present on the terminals of the DC voltage source (DCᵥₐᵣ) is or can be adjusted in accordance with a working frequency of the first oscillatory system (10).

In some embodiments, the first capacitor (Cᵥₐᵣ) is comprised of a plurality of parallel-connected capacitors C_{var,1}, . . . , C_{var,n}).

In some embodiments, the decoupling element (Lₑₙₜₖ) is an inductance.

In some embodiments, the parallel-connected arrangement of the first capacitor (Cᵥₐᵣ) and the series-connected arrangement of the DC voltage source (DCᵥₐᵣ) and the decoupling element (Lₑₙₜₖ) is connected in series with a second capacitor (C_{fest}).

In some embodiments, the second capacitor is frequency- and voltage stable.

In some embodiments, the capacitance value of the second capacitor (C_{fest}) is smaller than the capacitance value of the first capacitor (Cᵥₐᵣ).

In some embodiments, the coupling factor between the first oscillatory system (10) and the second oscillatory system (20) is smaller than 50%.

Some embodiments may include an oscillatory system (10) for the transmission of energy to another weakly-coupled oscillatory system (20), comprising an oscillating circuit having a frequency generator (11), a first coil (13) and a device (12) as described above.

Some embodiments may include an oscillatory system (20) for the reception of energy from another weakly-coupled oscillatory system (10), comprising a load (21), a second coil (23) and a device (22) as described above.

Some embodiments may include an energy transmission system, comprising a first oscillatory system (10) and a second oscillatory system (20), which is coupled with an unknown and weak coupling factor (K), wherein the first oscillatory system (10) comprises a device as described above.

In some embodiments, the second oscillatory system (20) comprises a device as described above.

### BRIEF DESCRIPTION OF THE DRAWINGS

The invention is described in greater detail hereinafter with reference to the exemplary embodiments in the drawing. Herein:

FIG. 1 shows a schematic representation of an energy transmission system,

FIG. 2 shows an equivalent electric circuit diagram of a first variant of a device according to the invention having an adjustable capacitance value,

FIG. 3 shows an equivalent electric circuit diagram of a second variant of a device according to the invention having an adjustable capacitance value,

FIG. 4 shows an equivalent electric circuit diagram of a third variant of a device according to the invention having an adjustable capacitance value,

FIG. 5 shows an equivalent electric circuit diagram of a fourth variant of a device according to the invention having an adjustable capacitance value.

### DETAILED DESCRIPTION

The teachings of the present disclosure may be embodied in a device having an adjustable capacitance value for tuning a first oscillatory system, which is provided for coupling with a second oscillatory system having an unknown and weak coupling factor. The device comprises a first capacitor, the capacitance of which is dependent upon a voltage, and a DC voltage source, the voltage of which applied to the terminals thereof can be controlled. The series-connected arrangement of the DC voltage source and a decoupling element is connected in parallel with the terminals of the capacitor, to apply a variable bias voltage to the first capacitor. The voltage present on the terminals of the DC voltage source is or can be adjusted in accordance with a working frequency of the first oscillatory system.

The device described is associated with lower losses, in comparison with a variant having bidirectional switching elements. The device occupies a smaller space, and can be produced cost-effectively. Specifically, as the first capacitor, a comparatively low-cost capacitor with a “low-grade” ceramic can be employed. In this case, the term “low-grade” relates to the stability of its capacitance in relation to the voltage lost therefrom.

In some embodiments, the first capacitor can be comprised of a plurality of parallel-connected capacitors. The number of capacitors, which can vary according to the design of an energy transmission system, can be used to determine the magnitude of the capacitance value of the first capacitor. In a known manner, the higher the number of parallel-connected capacitors, the greater the capacitance value. In an automotive field application for the transmission of energy to a secondary coil, the number may lie between 30 and 40.

In some embodiments, the decoupling element is an inductance. This ensures that an alternating current flowing via the first capacitor does not flow in the parallel path via the low-resistance DC voltage source.

In some embodiments, the parallel-connected arrangement of the first capacitor and the series-connected arrangement of the DC voltage source and the decoupling element can be connected in series with a second capacitor. For example, the second capacitor may be a frequency- and voltage-stable capacitor. The presence and dimensioning of the second capacitor depend upon the maximum and minimum capacitance values to be achieved in the oscillatory system.

In some embodiments, the selected capacitance value of the second capacitor is smaller than the capacitance value of the first capacitor. Accordingly, by the series connection of the first and second capacitor, it is ensured that the voltage loss via the first capacitor is sufficiently small, such that the capacitance value of the first capacitor does not vary in response to the alternating voltage applied thereto. It would otherwise not be possible to maintain the constant capacitance value on the first capacitor.

The design of the capacitance values on the first oscillatory system may be based upon two criteria.

As a first criterion, maximum coupling between the first oscillatory system and the second oscillatory system is assumed. Maximum coupling is then achieved in the event of an optimum offset (e.g., a zero offset) between the coils of the first oscillatory system and the second oscillatory system, and a minimum air gap. In this case, the stray inductances of both coils in the two oscillating circuits will be at their minimum value. The total capacitance value, given by the capacitance value of the first capacitor and of the optionally-provided second capacitor which is serially-connected thereto, is then at a maximum.

As a second criterion, minimum coupling between the coils of the first and second oscillatory system is assumed. Minimum coupling then occurs in the event of a maximum air gap and likewise a maximum offset between the coils of the first and second oscillatory system. In this case, the stray inductances of the coils in the first and second oscillatory system will be at their maximum value. In this configuration, the capacitance value of the device, which is given by the capacitance value of the first variable capacitor and of the optionally-provided second capacitor, is at a minimum.

The adjustment of the capacitance value, by the corresponding adjustment of voltage in relation to the working frequency of the first oscillatory system, then proceeds between the minimum capacitance value and the maximum capacitance value, which have been determined, as described above.

In some embodiments, the coupling factor between the first oscillatory system and the second oscillatory system is smaller than 50%. The working frequency of the first oscillatory system specifically lies between 80 kHz and 90 kHz.

Some embodiments may include an oscillatory system for the transmission of energy to another weakly-coupled oscillatory system, comprising an oscillating circuit having a frequency generator (current source), a first coil and a device of the aforementioned type. The function of the device having an adjustable capacitance value is the setting of a fixed working frequency on the oscillatory system within a predefined frequency range, between 80 kHz and 90 kHz, where the oscillatory system is to be employed for inductive energy transmission in the field of charging of electric vehicles.

Some embodiments may include an oscillatory system for the reception of energy from another weakly-coupled oscillatory system, comprising a load, a second coil, and a device having an adjustable capacitance value, of the aforementioned type. By the adjustment of the capacitance value of the oscillatory system for the reception of energy, for example by the application of a MPP (maximum peak power) method, the transmittable energy to the load can be maximized.

In some embodiments, an energy transmission system includes a first oscillatory system and a second oscillatory system, which is coupled with an unknown and weak coupling factor, wherein the first oscillatory system for the transmission of energy to the other second oscillatory system comprises a device having an adjustable capacitance value for the tuning of the first oscillatory system.

In some embodiments, the second oscillatory system incorporates a device having an adjustable capacitance value for tuning the second oscillating circuit, in order to ensure a maximization of the transmittable power to the load by the application of the MPP method.

Reference in the present description to an “unknown” coupling factor is attributable to the circumstance of the preferred application. One application of the energy transmission system described herein is the wireless charging of electric vehicles. In this application, depending upon the parking position of the vehicle containing the secondary coil over a first coil, e.g., in the floor of a parking space, the air gap (dictated by the vehicle type) and the offset (dictated by the parking position) may be subject to variation. The aforementioned design criteria take account of this circumstance.

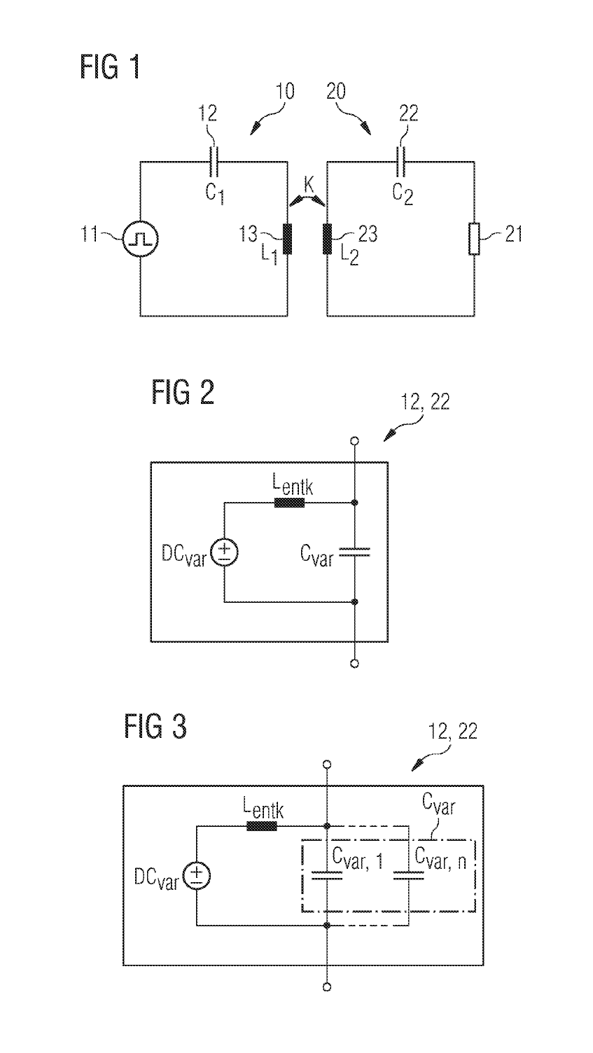

FIG. 1 shows a prior art energy transmission system, comprising a first oscillatory system 10 and a second oscillatory system 20. The first oscillatory system 10 comprises a frequency generator 11 (voltage source), a capacitor 12 with a capacitance value C₁ and a coil 13 with an inductance L₁. The first oscillatory system 10 constitutes a primary coil system of a device for the transmission of energy to the second oscillatory system 20. The first oscillatory system 10 can, for example, be set into the floor of a parking space, or arranged on the floor of the parking space.

The components of the second oscillatory system 20 comprise a load (an energy store), a second capacitor 22 with a capacitance value C₂ and a second coil 23 with an inductance L₂, and are, e.g., integrated in a vehicle. Where the vehicle is parked on the parking space, the coils are positioned one above the other, such that a mutual magnetic coupling K is constituted between the coils 13, 23 thereof, depending upon the parking position. As a result of the generally large air gap between the coils of the primary-side oscillatory system 10 and the secondary-side oscillatory system 20, in the range of 8 cm to 12 cm, coupling factors are generally lower than 50%.

The working frequency of the primary-side oscillatory system 10 is dictated by the inductance L₁ of the transformer formed by the primary-side and the secondary-side coils 13, 23, and of the primary-side coil 13 in conjunction with the primary-side capacitance value C₁. In order to ensure a fixed working frequency within a statutorily dictated frequency range between 80 kHz and 90 kHz for inductive vehicle charging systems, variable adjustment of the capacitance value C₁ of the capacitor 12 may be required in response to a varying load 21 or a variation in the inductance L₁ of the transformer or the coil 13.

The exemplary embodiments represented in FIGS. 2 to 5 permit the setting of the capacitance value C₁ of the capacitor 12 of the primary-side oscillatory system between a minimum capacitance value and a maximum capacitance value. Accordingly, the requirement for the fixed working frequency f to be set in a fixed manner can be ensured, even in the event of a varying load 21 or in the inductance L₁ or L₂.

FIG. 2 shows an example configuration of a variable capacitance. As a corresponding variable, capacitance can also be provided in the second oscillatory system 20. The exemplary embodiments of the variable capacitance in FIGS. 2 to 5 are identified by the reference numbers 12, 22.

As shown in FIG. 2, the variable capacitance 12, 22 comprises a first capacitor Cᵥₐᵣ, with a capacitance dependent upon a voltage, and a DC voltage source DCᵥₐᵣ, the voltage of which can be controlled. A series-connected arrangement of the DC voltage source DCᵥₐᵣ and a decoupling element Lₑₙₜₖ configured as an inductance are connected in parallel with the first capacitor Cᵥₐᵣ. Accordingly, a variable bias voltage can be applied to the first capacitor C_{var.} The voltage present on the terminals of the DC voltage source DCᵥₐᵣ is set in relation to a desired working frequency (between 80 kHz and 90 kHz) of the first oscillatory system 10. The first capacitor, which is highly voltage-dependent, is thus preloaded by means of the variable DC voltage source DCᵥₐᵣ, whereby the desired capacitance value setting is achieved. For the decoupling of the bias voltage of the components in the first oscillatory system, the inductance Lₑₙₜₖ is provided. For the setting of the variable capacitance 12, 22, a control function is employed, the manipulated variable of which is the DC voltage. The target value is thus derived from the desired working frequency of the first oscillatory system 10.

The exemplary embodiment according to FIG. 3 is distinguished from that in FIG. 2 in that the first capacitor Cᵥₐᵣ is comprised of a plurality of parallel-connected capacitors C_{var,1}, . . . , C_{var,n}. The number of parallel-connected capacitors is selected in accordance with the design of the energy transmission system.

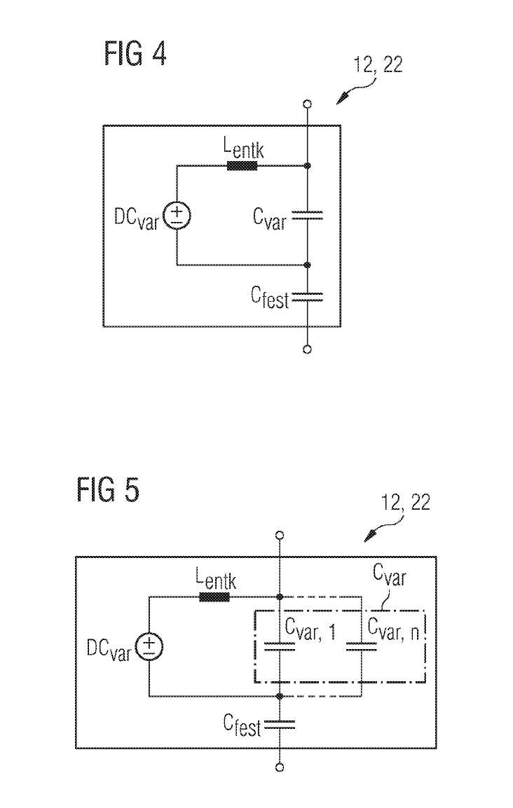

In the exemplary embodiments shown in FIGS. 4 and 5, additional to the variants represented in FIGS. 2 and 3, a second capacitor C_{fest} is connected respectively in series with the parallel-connected arrangement of the first capacitor Cᵥₐᵣ and the series-connected arrangement of the DC voltage source DCᵥₐᵣ and the decoupling element Lₑₙₜₖ. Conversely to the first capacitor Cᵥₐᵣ, the second capacitor is frequency- and voltage-stable. Moreover, the capacitance value of the second capacitor C_{fest} is smaller than the capacitance value of the first capacitor Cᵥₐᵣ.

The magnitude of the capacitance value can be set by the number of parallel-connected capacitors of the first capacitor and the optional fixed capacitor. If the second frequency- and voltage-stable capacitor is additionally provided, an exceptionally highly variable capacitance value can be achieved. The design of the overall capacitance value is based upon two criteria:

As a first criterion, maximum coupling between the first oscillatory system and the second oscillatory system is assumed. Maximum coupling is then achieved in the event of an optimum offset (e.g., a zero offset) between the coils of the first oscillatory system and the second oscillatory system, and a minimum air gap. In this case, the stray inductances of both coils in the two oscillating circuits will be at their minimum value. The total capacitance value, given by the capacitance value of the first capacitor and of the optionally-provided second capacitor which is serially-connected thereto, is then at a maximum.

As a second criterion, minimum coupling between the coils of the first and second oscillatory system is assumed. Minimum coupling then occurs in the event of a maximum air gap and likewise a maximum offset between the coils of the first and second oscillatory system. In this case, the stray inductances of the coils in the first and second oscillatory system will be at their maximum value. In this configuration, the capacitance value of the device, given by the capacitance value of the first variable capacitor and of the optionally-provided second capacitor, is at a minimum.

The provision of a variable capacitance in the first oscillatory system is intended to ensure a fixed working frequency of the resonant converter in the event of varying load or inductance. The provision of a variable capacitance in the second oscillatory system can be employed in the interests of maximizing the power transmitted via the transformer. To this end, the capacitance value of the second oscillatory system—once the working frequency has been determined by the setting of the capacitance value on the first oscillatory system—can be varied to maximize the power transmittable to the load 21, by the application of the MPP (maximum peak power) method.

What is claimed is:

1. A device having an adjustable capacitance value for tuning a first oscillatory system, provided for coupling with a second oscillatory system having an unknown and weak coupling factor, the device comprising:
a first capacitor having a capacitance dependent upon a voltage;
a DC voltage source having a variable voltage applied to associated terminals;
further comprising a series-connected arrangement of the DC voltage source and a decoupling element is connected in parallel with terminals of the capacitor, to apply a variable bias voltage to the first capacitor; and
wherein the voltage applied to the terminals of the DC voltage source depends at least in part on a working frequency of the first oscillatory system.

2. The device as claimed in claim 1, wherein the first capacitor comprises a plurality of parallel-connected capacitors.

3. The device as claimed in claim 1, wherein the decoupling element comprises an inductance.

4. The device as claimed in claim 1, further comprising the parallel-connected arrangement of the first capacitor and the series-connected arrangement of the DC voltage source and the decoupling element connected in series with a second capacitor.

5. The device as claimed in claim 4, wherein the second capacitor is frequency- and voltage stable.

6. The device as claimed in claim 4, wherein a capacitance value of the second capacitor is smaller than a capacitance value of the first capacitor.

7. The device as claimed in claim 1, wherein a coupling factor between the first oscillatory system and the second oscillatory system is less than 50%.

8. An oscillatory system for the transmission of energy to another weakly-coupled oscillatory system, comprising:
an oscillating circuit having a frequency generator;
a first coil;
a first capacitor having a capacitance dependent upon a voltage; and
a DC voltage source having a variable voltage applied to associated terminals;
further comprising a series-connected arrangement of the DC voltage source and a decoupling element connected in parallel with terminals of the capacitor, to apply a variable bias voltage to the first capacitor; and
wherein the voltage applied to the terminals of the DC voltage source depends at least in part on a working frequency of the first oscillatory system.

9. An oscillatory system for reception of energy from another weakly-coupled oscillatory system, comprising:
a load;
a second coil;
a first capacitor having a capacitance dependent upon a voltage; and
a DC voltage source having a variable voltage applied to associated terminals;
further comprising a series-connected arrangement of the DC voltage source and a decoupling element connected in parallel with terminals of the capacitor, to apply a variable bias voltage to the first capacitor; and
wherein the voltage applied to the terminals of the DC voltage source depends at least in part on a working frequency of the first oscillatory system.

10. An energy transmission system comprising:
a first oscillatory system; and
a second oscillatory system coupled with an unknown and weak coupling factor;
wherein the first oscillatory system comprises:
a first capacitor having a capacitance dependent upon a voltage; and
a DC voltage source having a variable voltage applied to associated terminals;
further comprising a series-connected arrangement of the DC voltage source and a decoupling element connected in parallel with terminals of the capacitor, to apply a variable bias voltage to the first capacitor; and
wherein the voltage applied to the terminals of the DC voltage source depends at least in part on a working frequency of the first oscillatory system.

11. The energy transmission system as claimed in claim 10, wherein the second oscillatory system comprises:
a first capacitor having a capacitance dependent upon a voltage; and
a DC voltage source having a variable voltage applied to associated terminals;
further comprising a series-connected arrangement of the DC voltage source and a decoupling element connected in parallel with terminals of the capacitor, to apply a variable bias voltage to the first capacitor; and
wherein the voltage applied to the terminals of the DC voltage source depends at least in part on a working frequency of the first oscillatory system.
